(19) United States
(12) Patent Application Publication
(10) Pub. No.: US 2022/0260319 A1
(43) Pub. Date: Aug. 18, 2022

(54) THERMOELECTRIC POWER GENERATION SYSTEM

(71) Applicants: INNOVATION THRU ENERGY CO., LTD., Tokyo (JP); TOHOKU TECHNO ARCH CO., LTD., Miyagi (JP)

(72) Inventor: Takahito ONO, Miyagi (JP)

(21) Appl. No.: 17/597,556

(22) PCT Filed: Jul. 2, 2020
(86) PCT No.: PCT/JP2020/026092

§ 371 Date: Jan. 11, 2022

(30) Foreign Application Priority Data
Jul. 11, 2019 (JP) 2019-129362

(51) Int. Cl. F28D 15/02; F28D 20/02; F25B 21/02; H02N 11/00

(52) U.S. Cl. CPC F28D 15/02; H02N 11/002; F25B 21/02; F28D 20/02

(57) ABSTRACT

[Problems] To provide a thermoelectric power generation system that has a relatively simple configuration, is not prone to failure, and is capable of efficiently generating power from temperature changes in the surrounding environment alone, even where there is no heat source.

[SOLUTION] A thermoelectric power generation device 13 is arranged between a heat storage body 11 having a phase-change material 11b and a heat exchange body 12 whose heat dissipation rate and/or heat absorption rate is greater than that of the heat storage body 11. The thermoelectric power generation device 13 is configured to generate electricity from the temperature difference between the heat storage body 11 and the heat exchange body 12. The thermoelectric power generation device 13 is plate-shaped, and one surface may be in contact with the heat storage body 11 and the other surface may be in contact with the heat exchange body 12.

### TECHNICAL FIELD

The present invention relates to a thermoelectric power generation system.

### BACKGROUND TECHNOLOGY

Conventionally, in order to obtain electric energy from thermal energy, various power generation devices have been developed. Among these power generation devices, there is a power generation device using a pyroelectric material whose polarization electrification changes with changes in temperature. In order to efficiently generate electricity, a power generation device using a pyroelectric material is configured to force a temperature change on the pyroelectric material by, for example, moving the pyroelectric material between a heating area such as a heat source and a cooling area (see, for example, Patent Document 1 or 2), or by rotating a rotating member to switch between heating and cooling states of the pyroelectric material (see, for example, Patent Document 3).

### PRIOR ART DOCUMENT

### Patent Documents

[Patent Document 1] Patent Publication No. 11-332266
[Patent Document 2] Patent Publication No. 2013-55824
[Patent Document 3]: Patent Publication No. 2015-82929

### INVENTION OVERVIEW

### Problems to be Resolved by the Invention

In the power generation devices described in Patent Documents 1 and 3, the power generation efficiency of the pyroelectric material is poor just by temperature changes in the surrounding environment, so the pyroelectric material is moved, or the rotating member is rotated. However, this requires a complex structure with moving and rotating operations, and the moving and rotating operations are likely to cause failure. Moreover, to force a temperature difference on the pyroelectric body, there was also a problem that it can only be used in a place where a heat source exists.

The present invention has been made to pay attention to such problems and has a relatively simple configuration that is resistant to failure and capable of efficiently generating power from temperature changes in the surrounding environment alone, even in places with no heat source.

### Way to Resolve the Problems

In order to achieve the above objective, the thermoelectric power generation system of the present invention is characterized in that it comprises a heat storage body consisting of a phase change material stored in a container with high thermal conductivity, a heat exchange body (a heat absorbing and heat dissipating body) having a higher heat dissipation rate and/or a heat absorption rate than the heat storage body, and it is characterized by having a thermoelectric power generation device arranged between the heat storage body and the heat exchanger body and configured to generate electricity from the temperature difference between the heat storage body and the heat exchanger body.

In the thermoelectric power generation system of the present invention, since there is a difference in the rate of heat dissipation and/or heat absorption between the heat storage body and the heat exchanger body when the temperature of the surrounding environment changes, a temperature difference is generated between the heat storage body and the heat exchanger body, and the thermoelectric power generation device can generate electricity using the temperature difference. In this way, the thermoelectric power generation system, according to the present invention, can efficiently generate electricity just by changing the temperature of the surrounding environment, even in places where there is no heat source or prior temperature difference.

The thermoelectric power generation system, according to the present invention, can generate electricity, if the heat exchange body has a higher heat dissipation rate than the heat storage body, a temperature difference between the heat storage body and the heat exchange body occurs easily when the temperature of the surrounding environment decreases. In case that the heat exchange body has a higher heat absorption rate than the heat storage body when the temperature of the surrounding environment rises, a temperature difference can easily be generated between the heat storage body and the heat exchange body, and power can be generated. If the heat exchange body has a higher heat dissipation and heat absorption rates than that of the heat storage body, each time the temperature surrounding the environment changes, a temperature difference occurs between the heat storage body and the heat exchange body, and power can be generated.

The thermoelectric power generation system, according to the present invention, has a relatively simple configuration with a heat storage body, a heat exchange body, and a thermoelectric power generation device, and does not have a complicated structure involving movement, rotation, or other actions. Because of this, failure due to movement, rotation and other movements unlikely to occur.

In the thermoelectric power generation system, according to the present invention, the thermoelectric power generation device may have a plate shape, one surface in contact with the heat storage body, and the other surface in contact with the heat exchange body. In this case, the temperature of the heat storage body and the temperature of the heat exchange body can be captured on the surface, and the power generation by the temperature difference between them can be performed efficiently.

In the thermoelectric power generation system of the present invention, it is preferable that the heat storage body has a substance that dissipates or absorbs heat in a small range of temperature changes in the surrounding environment in which it is used. It is preferred that the heat storage body has a phase change material whose melting point overlaps with the range of temperature changes of the surrounding environment in which it is used, for example, polyethylene glycol, paraffin, propylene glycol, and hydrated potassium fluoride etc. Further, it is also preferable that the heat storage material consists of the phase change material in a container with high thermal conductivity, such as a metal container. In this case, since the container has high thermal conductivity, the temperature of the heat storage body can be efficiently transferred to the thermoelectric power generator.

In the thermoelectric power generation system of the present invention, the heat exchange body can be made of any material that has a large heat dissipation rate and/or heat absorption rate, for example, it can be made of a heat sink. In this case, the heat dissipation speed and heat absorption speed can be increased, and the power generation efficiency can be improved. Further, the heat exchange body can be configured to dissipate heat by using the heat of vaporization of water. In this case, the speed of heat dissipation can be increased.

The thermoelectric power generation system, according to the present invention, can have a voltage-boosting unit that increases the output voltage generated by the thermoelectric power generation device. In this case, the electricity after boosting can be used to operate various sensors, and can be used as a power source. The voltage booster section consists of a voltage booster circuit, such as a DC-DC converter or charge pump circuit, for example.

The thermoelectric power generation system of the present invention preferably has a polarity adjustment section that makes the polarity of the output voltage generated by the thermoelectric power generation device when the temperature of the heat exchange body is higher than the temperature of the heat storage body, and the polarity of the output voltage generated by the thermoelectric power generation device would be identical when the temperature of the heat exchange body is lower than the temperature of the heat storage body. In this case, both the power generation output can be used when the temperature of the heat exchange body is higher than that of the heat storage body and the power generation output when the temperature of the heat exchange body is lower than that of the heat storage body, which can increase the efficiency of using the generated electricity.

### Effect of the Invention

According to the present invention, it is possible to provide a thermoelectric power generation system with a relatively simple configuration, which is not prone to failure and can efficiently generate electricity just from temperature changes in the surrounding environment, even in places without a heat source.

### SIMPLE EXPLANATION OF THE DRAWINGS

FIG. 1: it is a Vertical cross-sectional view which shows the thermoelectric power generation system of the present invention.

FIG. 2: it is a vertical cross-sectional view of a thermoelectric power generation system of an embodiment of the present invention, showing a variant in which the heat exchanger consists of a porous material containing water.

FIG. 3: it is a side view of the thermoelectric power generation system shown in FIG. 2, showing a variation of the system with a water source and water pipe.

FIG. 4: it is a circuit diagram showing (a) the first modification, and (b) the second modification of the thermoelectric power generation system with the polarity adjustment section.

FIG. 5: it is a vertical cross-sectional view of the thermoelectric power generation system shown in FIG. 1, showing the structure of the experiment to measure the generated power.

FIG. 6: Graphs of (a) the temperature T1 of the heat exchange body and the temperature T2 of the phase change material, and (b) the temperature T1 of the heat exchange body and the generated power (Power) P, showing the results of the measurement experiment of the generated power of the thermoelectric power generation system shown in FIG. 5.

FIG. 7: The graphs show the output from the thermoelectric power generation device (TEG output) and the generator power (DC-DC output) of the thermoelectric power generation system shown in FIG. 2, which is the result of an experiment to measure the generated power when the thermoelectric power generation device and the heat exchange body are in 1 set.

FIG. 8: The graph shows the output from the thermoelectric power generation device (TEG output) of the thermoelectric generation system shown in FIG. 2, when there are two sets of thermoelectric generators and heat exchange bodies.

FIG. 9: The block diagram shows a temperature measurement system when a temperature sensor is driven by using the generated power of the thermoelectric power generation system shown in FIG. 1.

FIG. 10: This graph shows the results of temperature measurement (a) indoors and (b) outdoors by the temperature measurement system shown in FIG. 9.

### FORM FOR IMPLEMENTING THE INVENTION

The following is a description of the present invention based on the drawings.

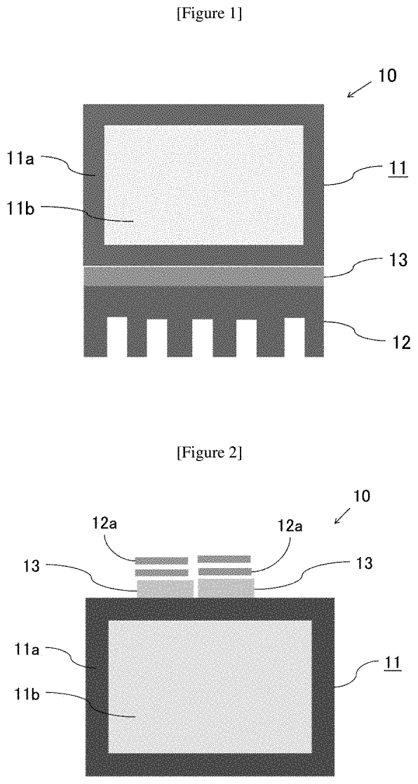

FIGS. 1 to 10 show a thermoelectric power generation system of an embodiment of the present invention.

As shown in FIG. 1, the thermoelectric power generation system 10 has a heat storage body 11, a heat exchange body 12, and a thermoelectric power generator 13.

The heat storage body 11 is formed by storing a phase change material (PCM) 11b inside a metal container 11a. The container 11a is made of copper, which has high thermal conductivity. The phase change material 11b consists of a material whose melting point overlaps the range of temperature change of the surrounding environment in which it is used, for example, in case used in normal room temperature or outside air temperature, polyethylene glycol 600, propylene glycol or the like is used. The phase change material 11b may consist of one type, or may be a mixture of several types.

The heat exchange body 12 is made of a heat sink that has a higher heat dissipation rate and heat absorption rate than the heat storage body 11. In addition to the heat sink, the heat exchange body 12 may also made of a body that has only one of the heat dissipation speed and the heat absorbing speed higher than that of the heat storage body 11.

The thermoelectric power generation device (TEG) 13 has a plate shape and is placed between the heat storage body 11 and the heat exchange body 12. The thermoelectric power generation device 13 is provided so that one surface contacts one surface of the container 11a of the heat storage body 11, and the other surface contacts the surface opposite to the uneven surface of the heat exchange body 12. The thermoelectric power generation device 13 has a thermoelectric conversion element, for example, Bi—Te group, Pb—Te group, Si—Ge group etc., and is configured to generate electricity from the temperature difference between the heat storage body 11 and the heat exchange body 12.

Next, explaining about the action.

In the thermoelectric power generation system 10, since there is a difference in the heat dissipation rate and heat absorption rate between the heat storage body 11 and the heat exchange body 12, so when the temperature of the surrounding environment changes, a temperature difference occurs between the heat storage body 11 and the heat exchange body 12, and the thermoelectric power generator 13 can generate electricity using the temperature difference. In this way, the thermoelectric power generation system 10 can efficiently generate electricity just by the temperature change of the surrounding environment, even in places where there is no heat source or no temperature difference beforehand.

The thermoelectric power generation system 10 has a relatively simple configuration with a heat storage body 11, a heat exchange body 12, and a thermoelectric power generation device 13, and does not have a complicated structure involving movement, rotation, or other actions. Because of this, failures caused by movement, rotation, and other operations are unlikely to occur. In the thermoelectric power generation system 10, since the heat storage body 11 and the thermoelectric power generation device 13, and the heat exchange body 12 and the thermoelectric power generation device 13 are in contact with each other face to face, the temperature of the heat storage body 11 and the temperature of the heat exchange body 12 can be captured on a surface, and power generation by the temperature difference between them can be performed efficiently.

The thermoelectric power generation system 10 can efficiently transfer the temperature of the heat storage 11 to the thermoelectric power generation device 13 because the heat storage 11 consists of a copper container 11a with a phase change material 11b inside. In addition, since the heat exchange body 12 consists of a heat sink, the heat dissipation rate and heat absorption rate are large, and the power generation efficiency can be increased. Because of this, the thermoelectric power generation system 10 can efficiently generate electricity even with slight temperature changes in the surrounding environment. In this way, the thermoelectric power generation system 10 can be used as a power source, for example, in places where solar power cannot be used, such as in containers or tunnels, because it can generate power with slight temperature changes.

Furthermore, In case the thermoelectric power generation system 10 uses a heat exchange body 12, which only dissipates heat at a faster rate than the heat storage body 11, a temperature difference can easily be generated between the heat storage body 11 and the heat exchange body 12 when the temperature of the surrounding environment drops, and power can be generated. In the case of using a heat sink 12, which only exchanges heat at a higher rate than the heat storage 11, when the temperature of the surrounding environment rises, a temperature difference can easily be generated between the heat storage 11 and the heat sink 12, and power can be generated.

As shown in FIG. 2, in the thermoelectric power generation system 10, the heat exchange body 12 may be made of a porous body 12a, such as cloth containing water. In this case, the heat of vaporization of the water can be used to dissipate the heat. In addition, it can be constructed relatively easily by using familiar cloth etc. In the specific example shown in FIG. 2, two sets of thermoelectric generators 13 and heat exchange body 12 are placed on the surface of one large heat storage container 11a, but it is not limited to two sets, it may be one or three or more sets.

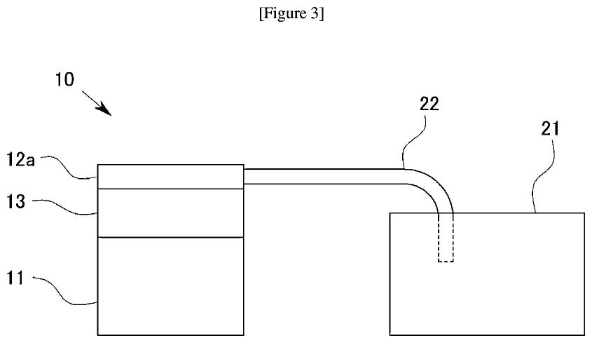

In the case shown in FIG. 3, the water source 21 and the water pipe 22 may be provided so that water can always be supplied to the porous body 12a from the water source 21 through the water pipe 22. In this case, water in the porous body 12a can be prevented from running out and power can be generated continuously. The water source 21 is, for example, something that exists in the ground or underground, or an arbitrarily provided water tank. The water pipe 22 is, for example, a capillary.

The thermoelectric power generation system 10 may have a boosting unit that increases the output voltage generated by the thermoelectric power generation device 13. In this case, the electricity from the boosting unit can be used to operate various sensors and the like, and can be used as a power source. The voltage booster section, for example, consists of a voltage booster circuit, such as a DC-DC converter or charge pump circuit.

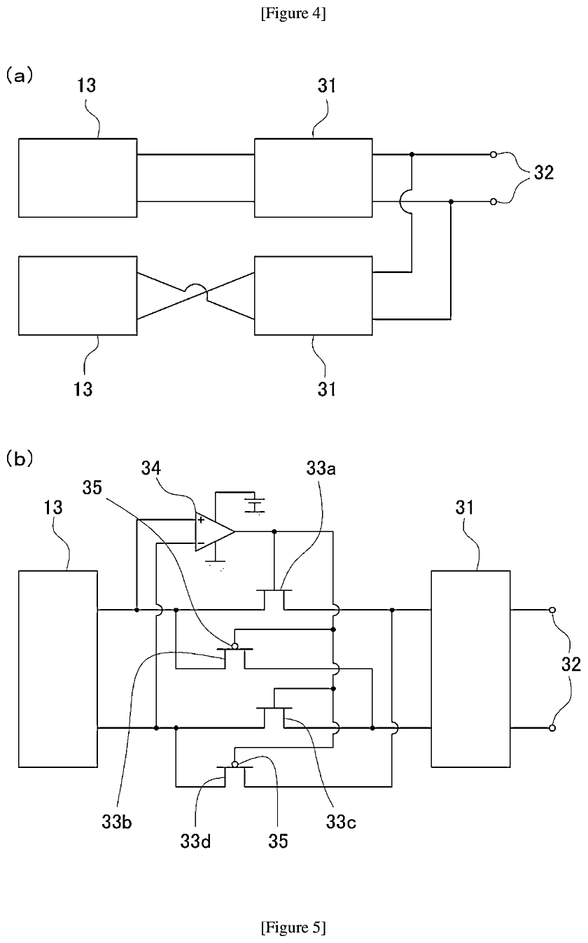

The thermoelectric power generation system 10 may have a polarity adjusting section that makes the polarity of the output voltage generated by the thermoelectric power generation device 13 when the temperature of the heat exchange body 12 is higher than the temperature of the heat storage body 11 the same as the polarity of the output voltage generated by the thermoelectric power generation device 13 when the temperature of the heat exchange body 12 is lower than the temperature of the heat storage body 11. In this case, the power output can be used for both cases when the temperature of the heat storage body 12 is higher than the temperature of the heat exchange body 11 and when the temperature of heat exchange body 12 is lower than the temperature of the heat storage body 11. This configuration increases the efficiency of using the generated electricity, and can be realized, for example, by FIGS. 4(a) and 4(b).

That is, as shown in FIG. 4(a), the thermoelectric power generation system 10 has at least two thermoelectric power generation devices 13, and also has two voltage booster circuits 31 as polarity adjustment sections, wherein the output of one thermoelectric power generation device 13 is input to one voltage booster circuit 31, and the output of the other thermoelectric power generation device 13 is reversed in polarity and input to the other output of one thermoelectric power generation device 13 is input to one voltage multiplier 31, and the output of the other thermoelectric power generation device 13 is input to the other voltage multiplier 31 with the polarity reversed, and the same polarity of the outputs of each voltage multiplier 31 may be connected to each other. Furthermore, In FIG. 4(a), when the difference between the output voltage of the upper terminal and the output voltage of the lower terminal in the figure is positive, it is referred as “positive polarity” and when the difference is opposite, it is referred as “negative polarity”.

In this case, when each thermoelectric power generation device 13 is installed and used in the same location and the output of each thermoelectric power generation device 13 is positive polarity, the output of one thermoelectric power generation device 13 is boosted by one voltage booster circuit 31, while the output of the other thermoelectric power generation device 13 is not output from the other voltage booster circuit 31 because the polarity is reversed. Because of this, the output of one thermoelectric power generation device 13 is output from the output terminal 32. And, when the output of each thermoelectric power generation device 13 has a negative polarity, the output of one thermoelectric power generation device 13 is not output from the other boost circuit 31, and the output of the other thermoelectric power generation device 13 is boosted by the other boost circuit 31 because the polarity is reversed. Therefore, the output of the other thermoelectric power generation device 13 is output from the output terminal 32. In this way, both the positive and negative polarity outputs of each thermoelectric power generation device 13 can be utilized.

And, As shown in FIG. 4(b), the thermoelectric power generation system 10 has four field-effect transistors 33a, 33b, 33c, 33d, one amplifier 34, and one boost circuit 31 as the polarity adjusting unit, and the first field-effect transistor 33a has its source connected to the output of one of the thermoelectric power generation devices 13, and its drain connected to one input of the boost circuit 31, the second field effect transistor 33b has its source connected to one output of the thermoelectric power generation device 13 and its drain connected to the other input of the boost circuit 31, and the third field effect transistor 33c has its source connected to the other output of the thermoelectric power generation device 13 and its drain connected to the boost circuit 31, the fourth field effect transistor 33d has its source connected to the other output of the thermoelectric power generation device 13 and its drain connected to one input of the boost circuit 31, and the amplifier 34 has its positive input connected to one output of the thermoelectric power generation device 13 and its negative input connected to the other input of the thermoelectric power generation device 13, and an output connected directly to the gates of the first field-effect transistor 33a and the third field-effect transistor 33c, and connected to the gates of the second field-effect transistor 33b and the fourth field-effect transistor 33d via an inverting circuit 35. Furthermore, Also in FIG. 4(b), when the difference between the output voltage of the upper (one) terminal and the output voltage of the lower (other) terminal in the figure is positive, it is referred to as “positive polarity” and vice versa as “negative polarity”.

In this case, when the output of the thermoelectric power generation device 13 has positive polarity, the positive output of the amplifier 34 applies a voltage to the gates of the first field-effect transistor 33a and the third field-effect transistor 33c, and a current flows between the source and the drain of the first field-effect transistor 33a and the third field-effect transistor 33c, and a current flows between the source and the drain of the first field effect transistor 33a and the third field effect transistor 33c. Since no voltage is applied to the gate of the second field effect transistor 33b and the fourth field effect transistor 33d, no current flows between the source and drain of the second field effect transistor 33b and the fourth field effect transistor 33d. Because of this, the output of the thermoelectric power generation device 13 is directly input to the booster circuit 31, where it is boosted and output with positive polarity. And, When the output of the thermoelectric power generation device 13 is of negative polarity, no voltage is applied to the gates of the first field-effect transistor 33a and the third field-effect transistor 33c due to the negative output of the amplifier 34, so no current flows between the source and the drain of the first field-effect transistor 33a and the third field-effect transistor 33c. And, a voltage is applied to the gates of the second field-effect transistor 33b and the fourth field-effect transistor 33d, and current flows between the source and drain of the second field-effect transistor 33b and the fourth field-effect transistor 33d. Because of this, the polarity of the output of the thermoelectric power generation device 13 is inverted and input to the booster circuit 31, where it is boosted and output as positive polarity. In this way, both the positive and negative polarity of the output of the thermoelectric power generation device 13 can be used.

### Practical Example 1

Using the thermoelectric power generation system 10 shown in FIG. 1 was used to measure the power generated when the ambient temperature was changed. In the experiment, the size of the container 11a of the heat storage body 11 was 5 cm×5 cm×3 cm, and polyethylene glycol 600 (melting point: 15° C. to 25° C.) was used as the phase change material 11b. And, the thermoelectric power generation device 13 was used with a thermal resistance of 1.79 K/W. As shown in FIG. 5, the experiment was conducted by storing the thermoelectric power generation system 10 inside a constant temperature bath 41 and changing the temperature inside constant temperature bath 41 intermittently between 5° C. and 35° C. During the experiment, thermocouples 42 were used to measure the temperature T1 of the heat exchange body 12, and thermocouples 43 were used to measure the temperature T2 of the phase-change material 11b. And, a voltmeter 44 was used to measure the output voltage from the thermoelectric power generator 13 across a load resistance of 12Ω to obtain the generated power P. furthermore, Since the heat exchange body 12 has a large heat dissipation rate and heat absorption rate, the temperature T1 of the heat exchange body 12 is considered to be almost the same as the temperature inside the constant temperature bath 41.

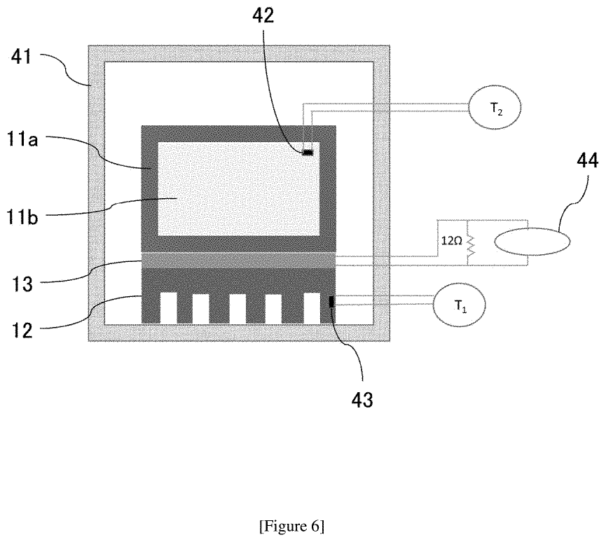

The experimental results are shown in FIGS. 6(a) and 6(b). As shown in FIG. 6(a), it was confirmed that the temperature T1 of the heat exchange body 12 responded quickly to the temperature change inside the thermostatic bath 41 and changed intermittently, while the temperature T2 of the phase change material 11b changed slowly, lagging behind the change in the temperature T1 of the heat exchange body 12. And, As shown in FIG. 6(b), the generated power (Power) P showed a peak every time the temperature T1 of the heat exchange body 12 changed, and it was confirmed that the peak became larger when the temperature changed within the range of the melting point (transformation point) of the phase change material 11b. And it was also confirmed that the generated power P corresponded to the difference between T1 and T2 shown in FIG. 6(a).

### Practical Example 2

The thermoelectric power generation system 10 shown in FIG. 2 was used to measure the generated power. In the experiment, the size of the container 11a of the heat storage 11 was 5 cm×5 cm×3 cm, and polyethylene glycol 600 (melting point: 15° C. to 25° C.) was used as the phase change material 11b. And, the thermoelectric generation device 13, a thermal resistance of 1.79 K/W was used. A cloth with a size of 1 cm×1 cm was used for the heat exchange body 12. Only one set of the thermoelectric power generation device 13 and the heat exchange body 12 was used. The experiment was set up in a room at constant temperature, and the output of the thermoelectric power generation device 13 and the power generated from the boost circuit (DC-DC Converter) connected to the thermoelectric power generation device 13 were measured when water droplets were dropped on the cloth of the porous body 12a.

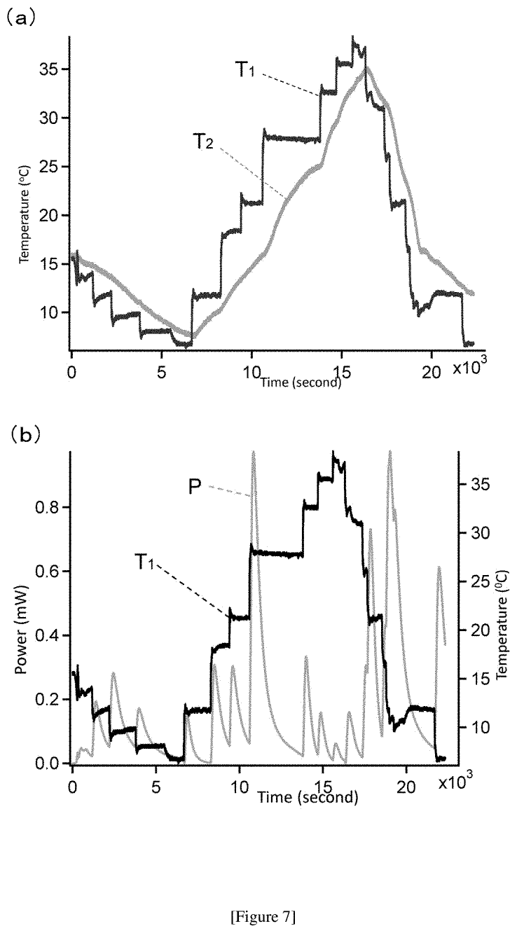

The experimental results are shown in FIG. 7. As shown in FIG. 7, it was confirmed that when a drop of water was dropped, an output (TEG Output) was obtained from the thermoelectric power generation device 13 and electric power (DC-DC Output) was generated because of the temperature difference between the heat exchange body 12 and the heat storage body 11. And, It was also confirmed that with the passage of time, as the water in the heat exchange body 12 evaporates, the temperature difference between the heat exchange body 12 and the heat storage body 11 becomes smaller, and both the output from the thermoelectric power generation device 13 and the power generated gradually decrease.

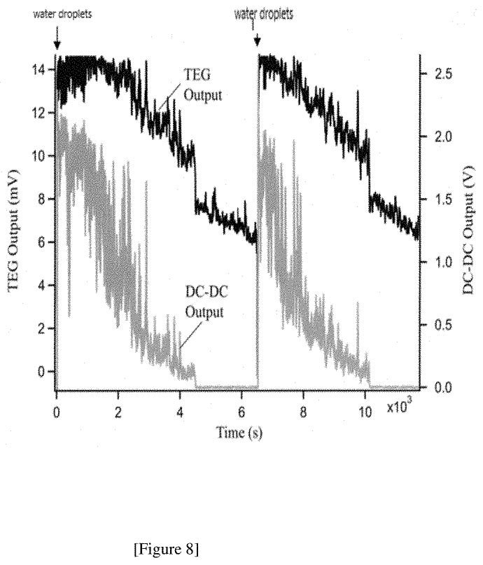

The same thermoelectric power generation device 13 and heat exchange body 12 used in the experiment in FIG. 7 were used in two sets, and the output of the thermoelectric power generation device 13 was measured in the same way. The experimental results are shown in FIG. 8. As shown in FIG. 8, similar to FIG. 7, the output (TEG Output) from the thermoelectric power generation device 13 was obtained when a drop of water was dropped, and it was confirmed that the output from the thermoelectric power generation device 13 gradually decreased with time. And, Compared to FIG. 7, the output from the thermoelectric power generation device 13 is approximately doubled because two sets of the thermoelectric power generation device 13 and the heat exchange body 12 are used.

### Practical Example 3

Temperature measurement experiments were conducted indoors and outdoors by driving a temperature sensor using the power generated from the thermoelectric power generation system 10 shown in FIG. 1. In the experiments, the size of container 11a of the heat storage body 11 was 5 cm×5 cm×3 cm, and polyethylene glycol 600 (melting point: 15° C.-25° C.) was used as the phase change material 11b. And, the thermoelectric power generation device 13, a thermal resistance of 1.79 K/W was used.

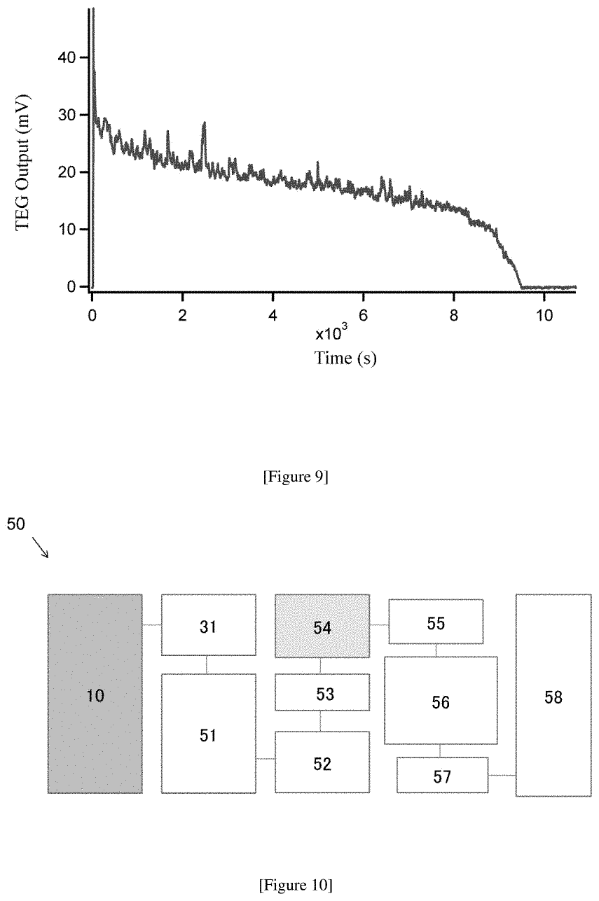

The temperature measurement system 50 is shown in FIG. 9. As shown in FIG. 9, the output of the thermoelectric power generation device 13 of the thermoelectric generation system 10 is boosted by the voltage booster circuit 31, rectified by the super capacitor (electric double layer capacitor) 51, and then the voltage value is further prepared by the DC-DC converter 52, and is supplied to the temperature sensor 54 via the timer 53. The measured values of the temperature sensor are also fed to the temperature sensor 54 via the timer 53. The measured values of the temperature sensor are converted to digital signals and stored in a memory 55, then converted to transmission signals by a signal processor 56, and wirelessly transmitted from an RF front end 57 to a personal computer through an antenna 58.

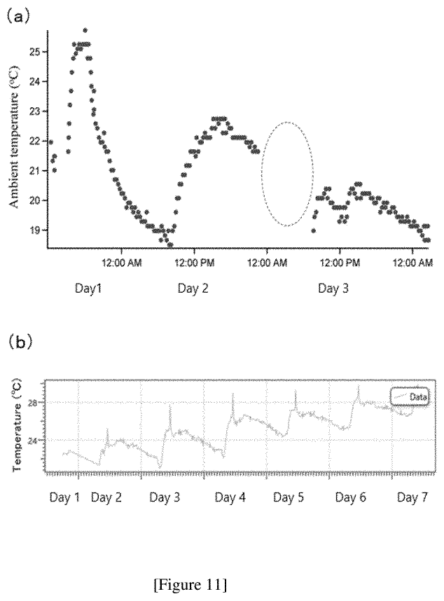

The results of the indoor and outdoor temperature measurements are shown in FIGS. 10(a) and (b), respectively. As shown in FIG. 10, daily changes in temperature were captured both indoors and outdoors, and it was confirmed that power could be supplied to the temperature sensor. Furthermore, the missing data during the night from the second to the third day in FIG. 10(a) (the area surrounded by broken lines in the figure) is due to the fact that the personal computer went into standby mode and did not receive any data. And, the spike-shaped peak during the daytime in FIG. 10(b) is due to the temperature sensor being exposed to direct sunlight.

### EXPLANATION OF THE CODE

10 Thermoelectric Power Generation System
11 Heat storage body
11a Container
11b Phase change material
12 Heat exchange body
13 Thermoelectric generation device
12a Porous material
21 Water source
22 Water pipe
31 booster circuit
32 Output terminals
33a, 33b, 33c, 33d Field-effect transistors
34 Amplifiers
35 Inverting circuit
41 constant temperature bath
42, 43 Thermocouple
44 Voltmeter
50 Temperature Measurement System
51 Supercapacitor
52 DC-DC converter
53 Timer
54 Temperature Sensor
55 Memory
56 Signal Processor
57 RF Front End
58 Antenna

1. The thermoelectric power generation system is characterized by the following,
A heat storage body consisting of a phase change material in a container with high thermal conductivity,
A heat exchange body having a higher heat dissipation rate and/or a higher heat absorption rate than those of the heat storage body, and
A thermoelectric generator placed between the heat storage body and the heat exchange body, and configured to generate electricity from the temperature difference between the heat storage body and the heat exchange body.

2. The thermoelectric power generation system of claim 1, wherein the thermoelectric power generation device is plate-shaped, and one surface is in contact with the heat storage body and the other surface is in contact with the heat exchange body.

3. The thermoelectric power generation system as claimed in claim 1 or 2, characterized in that the heat storage body consists of a metal container containing the phase-change material.

4. The thermoelectric power generation system as claimed in any one of claims 1 to 3, characterized in that the heat exchange body comprises a heat sink.

5. The thermoelectric power generation system as claimed in any one of claims 1 to 4, characterized in that the heat sink is configured to dissipate heat by utilizing the heat of vaporization of water.

6. A thermoelectric power generation system as claimed in any one of claims 1 to 5, characterized by a voltage booster unit that increases the voltage of the output generated by the thermoelectric power generator.

7. A thermoelectric power generation system as claimed in any one of claims 1 to 6, characterized in that it has a polarity adjusting unit having the same polarity of the output voltage generated by the thermoelectric power generation system when the temperature of the heat exchange body is higher than that of the heat storage body, and the polarity of the output voltage generated by the thermoelectric power generation system when the temperature of the heat exchange body is lower than that of the heat storage body.

8. The thermoelectric power generation system as claimed in claim 7, characterized by the following,
The thermoelectric generator consists of two of them, the polarity adjustment section has two voltage booster circuits,
The output of one thermoelectric generator is input to one of the voltage booster circuits, and the output of the other thermoelectric generator is connected to be input to the other voltage booster circuit with reversed polarity,
And the output of the voltage booster circuits with same polarity is connected to each other.

9. The thermoelectric power generation system as claimed in claim 8, characterized by the following,
The polarity adjustment unit has a first field effect transistor, a second field effect transistor, a third field effect transistor, a fourth field effect transistor, an amplifier, and a voltage booster circuit,
The first field-effect transistor has its source connected to one output of the thermoelectric generator and its drain connected to one input of the voltage booster circuit,
The second field-effect transistor has its source connected to one output of the thermoelectric generator and its drain connected to the other input of the amplifier.
The third field-effect transistor has its source connected to the other output of the thermoelectric generator and its drain connected to the other input of the amplifier.
The fourth field-effect transistor has its source connected to the other output of the thermoelectric generator and its drain connected to the other input of the amplifier.
The amplifier has its positive input connected to one output of the thermoelectric generator, its negative input connected to other output of the thermoelectric generator, and its output connected to the gates of the first field-effect transistor and the third field-effect transistor, as well as to the gates of the second field-effect transistor and the fourth field-effect transistor via an inverting circuit.
